(19) United States
(12) Patent Application Publication
(10) Pub. No.: US 2026/0245939 A1
(43) Pub. Date: Aug. 20, 2026

(54) FUEL CELL ASSEMBLY

(71) Applicant: GM GLOBAL TECHNOLOGY OPERATIONS LLC, Detroit, MI (US)

(72) Inventors: Joseph HAHN, White Lake Charter Township, MI (US); Anthony George CHINNICI, Utica, MI (US); Brian PODCZERVINSKI, West Bloomfield, MI (US)

(21) Appl. No.: 19/057,352

(22) Filed: Feb. 19, 2025

(51) Int. Cl. H01M 8/2475; H01M 8/04029; H01M 8/2483

(52) U.S. Cl. CPC H01M 8/2475; H01M 8/04029; H01M 8/2483

(57) ABSTRACT

A fuel cell assembly including: a first sidewall mounted to a base, the first sidewall including a first rail configured to cooperate with a fuel cell stack subassembly; a second sidewall mounted to the base opposite to the first sidewall including a second rail; a wet end unit mounted to wet ends of each of the first sidewall and the second sidewall, the wet end unit defining a plurality of manifolds configured to deliver hydrogen, oxygen, and coolant to the fuel cell stack subassembly; a first electronics housing mounted to dry ends of each of the first sidewall and the second sidewall; and a second electronics housing mounted to each one of the first sidewall, the second sidewall, the wet end unit, and the first electronics housing to provide a cover of a fuel cell housing configured to house the fuel cell stack subassembly.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to a fuel cell assembly configured to house a stack of fuel cells.

A fuel cell is an electrochemical device that converts the chemical energy of a fuel directly into electricity through a reaction with an oxidizing agent. The fuel is typically hydrogen, and the oxidizing agent is typically oxygen. The basic components of a fuel cell are an anode, a cathode, and an electrolyte. Fuel cells are suitable for use in various applications including automotive and portable power sources, for example.

### SUMMARY

The present disclosure provides for, in various features, a fuel cell assembly including: a base; a first sidewall mounted to the base, the first sidewall including a first rail extending along a first interior surface of the first sidewall, the first rail configured to cooperate with a fuel cell stack subassembly; a second sidewall mounted to the base opposite to the first sidewall, the second sidewall including a second rail extending along a second interior surface of the second sidewall, the second rail configured to cooperate with the fuel cell stack subassembly; a wet end unit mounted to wet ends of each of the first sidewall and the second sidewall, the wet end unit defining a plurality of manifolds configured to deliver hydrogen, oxygen, and coolant to the fuel cell stack subassembly; a first electronics housing mounted to dry ends of each of the first sidewall and the second sidewall; and a second electronics housing mounted to each one of the first sidewall, the second sidewall, the wet end unit, and the first electronics housing to provide a cover of a fuel cell housing configured to house the fuel cell stack subassembly.

In further features, at least the first sidewall, the second sidewall, and the wet end unit are formed from a non-metallic, composite material.

In further features, the base is formed of the non-metallic, composite material.

In further features, the first sidewall defines a first groove extending along a first exterior surface of the first sidewall opposite to the first rail; and the second sidewall defines a second groove extending along a second exterior surface of the second sidewall opposite to the second rail.

In further features, the first electronics housing includes a power sensing module and the second electronics housing includes a power conversion unit in wired communication with the power sensing module by way of a passageway defined between the first electronics housing and the second electronics housing.

In further features, at least one of the first electronics housing and the second electronics housing is made of a non-metallic composite material.

In further features, the first electronics housing is a dry end unit of the fuel cell assembly.

In further features, the first electronics housing includes electrical connectors configured for connection to a load to deliver electricity generated by the fuel cell assembly to the load.

In further features, the plurality of manifolds of the wet end unit includes an air inlet, an air outlet, a coolant inlet, a coolant outlet, and a hydrogen inlet.

In further features, the first sidewall defines a window in fluid communication with the hydrogen inlet and hydrogen injectors mounted to the first sidewall, the hydrogen injectors configured to cooperate with a hydrogen source for delivering hydrogen to the fuel cell stack subassembly.

In further features, a wet end manifold including a first end plate is mounted to the first sidewall and the second sidewall, and a second end plate is mounted to the first end plate, wherein the plurality of manifolds are defined by the wet end unit, the first end plate, and the second end plate, and the plurality of manifolds include a hydrogen manifold and a hydrogen ejector.

In further features, a drain is in fluid communication with the fuel cell housing configured to drain coolant out of the fuel cell housing.

In further features, the first rail is integrally formed with the first sidewall, and the second rail is integrally formed with the second sidewall; and cooperation between the first rail and the fuel cell stack subassembly, and cooperation between the second rail and the fuel cell stack subassembly, restricts movement of the fuel cell stack within the fuel cell housing.

In further features, the fuel cell housing is defined by the base, the first sidewall, the second sidewall, the wet end unit, the first electronics housing, and the second electronics housing.

The present disclosure also provides for, in various features, a fuel cell assembly including: a wet end unit made of a non-conductive composite material and defining a plurality of manifolds configured to deliver hydrogen, oxygen, and coolant to a fuel cell stack subassembly seated within the fuel cell assembly; a first electronics housing including first power components and electrical connectors configured for connection to a load to deliver electricity generated by the fuel cell assembly to the load; a first sidewall made of the non-conductive composite material and extending from the wet end unit to the first electronics housing; a second sidewall made of the non-conductive composite material and extending from the wet end unit to the first electronics housing; a base mounted to the first electronics housing, the first sidewall, and the second sidewall; a second electronics housing including second power components, the second electronics housing mounted to the wet end unit, the first electronics housing, the first sidewall, and the second sidewall; and a fuel cell housing defined by each of the wet end unit, the first electronics housing, the first sidewall, the second sidewall, the base, and the second electronics housing, the fuel cell housing configured to house the fuel cell stack subassembly therein.

In further features, the first sidewall includes an integral first rail at a first inner surface of the first sidewall; the second sidewall includes an integral second rail at a second inner surface of the second sidewall; and the fuel cell stack subassembly is in cooperation with each of the integral first rail and the integral second rail to restrict movement of the fuel cell stack subassembly within the fuel cell housing.

In further features, the first electronics housing and the second electronics housing each include a composite material bonded with an electromagnetic compatibility (EMC) shield.

The present disclosure also provides for, in various features, a fuel cell assembly including the following: a base; a first sidewall mounted to the base; a second sidewall mounted to the base; a wet end unit mounted to wet ends of each of the first sidewall and the second sidewall, the wet end unit defining a plurality of manifolds for hydrogen, oxygen, and coolant; a first electronics housing mounted to dry ends of each of the first sidewall and the second sidewall, the first electronics housing including a power sensing module therein; a second electronics housing mounted to each one of the first sidewall, the second sidewall, the wet end unit, and the first electronics housing, the second electronics housing including a power conversion unit in wired connection with the power sensing module by way of a passageway defined between the first electronics housing and the second electronics housing; a fuel cell housing defined by each of the base, the first sidewall, the second sidewall, the wet end unit, the first electronics housing, and the second electronics housing; and a fuel cell stack subassembly seated within the fuel cell housing and in cooperation with a first rail of the first sidewall and a second rail of the second sidewall, the plurality of manifolds are in fluid cooperation with the fuel cell stack subassembly to deliver hydrogen, oxygen, and coolant thereto. The first sidewall, the second sidewall, and the wet end unit are formed of a non-conductive polymeric material.

In further features, the base, the first electronics housing, and the second electronics housing are formed of the non-conductive polymeric material.

In further features, a drain is in fluid communication with the fuel cell housing configured to drain coolant out of the fuel cell housing.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a perspective view of a fuel cell assembly in accordance with the present disclosure;

FIG. 2 is another perspective view of the fuel cell assembly of FIG. 1;

FIG. 3 is a cross-sectional view of the fuel cell assembly of FIG. 1 taken along line 3-3 of FIG. 1;

FIG. 4 is another cross-sectional view of the fuel cell assembly of FIG. 1 taken along line 4-4 of FIG. 1; and

FIG. 5 is a perspective view of the fuel cell assembly of FIG. 1 showing a wet end of the fuel cell assembly.

In the drawings, reference numbers may be reused to identify similar and/or identical elements.

### DETAILED DESCRIPTION

The present disclosure includes a fuel cell assembly configured to house a stack of fuel cells. The fuel cells are electrochemical devices that convert chemical energy of a fuel into electricity through a chemical reaction with an oxidizing agent. The fuel is typically hydrogen and the oxidizing agent is typically oxygen. The fuel cell assembly is configured for use in any suitable application to supply power. For example, the fuel cell assembly may be configured for automotive and non-automotive applications. The fuel cell assembly of the present disclosure may be used to supply electricity for any suitable vehicle, such as any suitable fully electric vehicle, hybrid electric vehicle, etc. Suitable vehicles include, but are not limited to, passenger vehicles, commercial vehicles, public transportation vehicles, construction vehicles (and construction equipment), locomotives, watercraft, etc. With respect to non-automotive applications, the fuel cell assembly may be configured for use as a portable generator, a mobile electric charging system, or a building generator, for example.

The fuel cell assembly generally includes a base, first and second sidewalls mounted to the base, a wet end unit mounted to wet ends of the first and second sidewalls, a first electronics housing mounted to dry ends of the first and second sidewalls, and a second electronics housing mounted to each one of the first sidewall, the second sidewall, the wet end unit, and the first electronics housing. A fuel cell housing is defined by each of the base, the first sidewall, the second sidewall, the wet end unit, the first electronics housing, and the second electronics housing. The second electronics housing generally provides a cover of the fuel cell housing. A fuel cell stack is seated within the fuel cell housing.

At least the first sidewall, the second sidewall, and the wet end unit are made of a non-conductive composite material. The first electronics housing and the second electronics housing may each be made of a metallic material or the non-conductive composite material. The composite material may be bonded with an electromagnetic compatibility (EMC) shield. Within the first electronics housing is a power sensing module, and within the second electronics housing is a power conversion unit, as described herein. Electrical connectors at an exterior of the first electronics housing are readily accessible to allow the assembly to be connected to any suitable load. The fuel cell assembly is configured to be readily “plugged-in” to any suitable application (automotive or non-automotive) to supply power thereto.

The fuel cell assembly integrates each of the fuel cell housing, the first electronics housing, and the second electronics into a single assembly, which is easy to transport and install. The use of non-conductive composite materials for at least the sidewalls and the wet end unit provides the fuel cell assembly with a manageable weight, which further facilitates transport and installation. Rails included at interior surfaces of each of the sidewalls are configured to cooperate with the fuel cell stack to facilitate insertion of the stack and/or individual fuel cells thereof into the fuel cell housing. Cooperation between the rails the fuel cell stack also secures the fuel cell stack in position to prevent movement of the stack and/or individual cells thereof, such as during operation of a vehicle including the fuel cell assembly.

Forming the wet end unit of a composite material allows for various fluid flow channels/manifolds to be formed integrally therein, thereby reducing the number of components and connectors required. Integration of the fuel cell housing, the first electronics housing, and the second electronics housing together enhances structural rigidity of the assembly, reduces packaging size, and reduces overall weight of the assembly. This integration also reduces the number of connections and components required in the system. The fuel cell assembly of the present disclosure provides direct interfacing to external balance of plant sub-systems including anode, cathode, and thermal management components, thereby eliminating various manifolds for such connections.

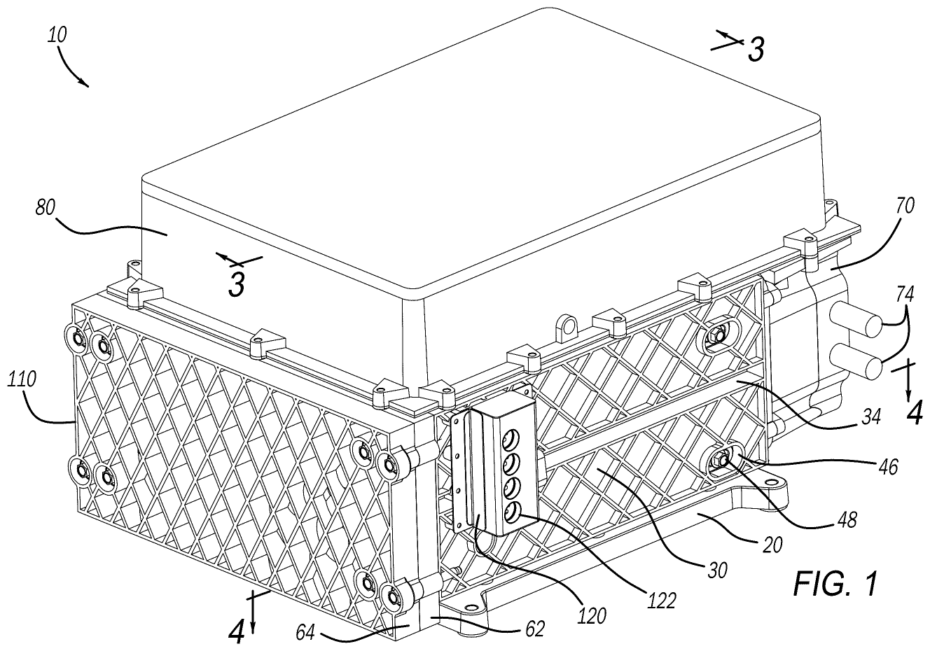

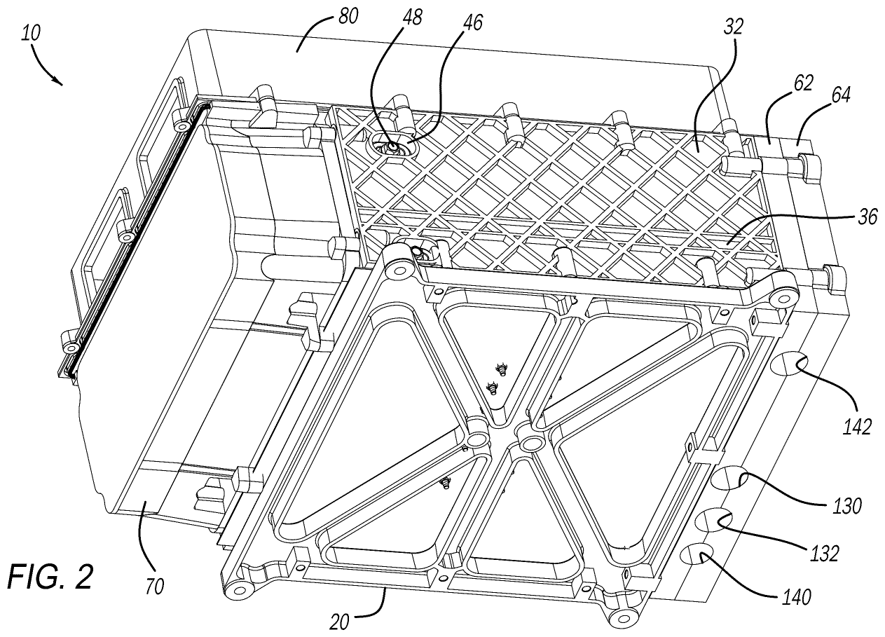

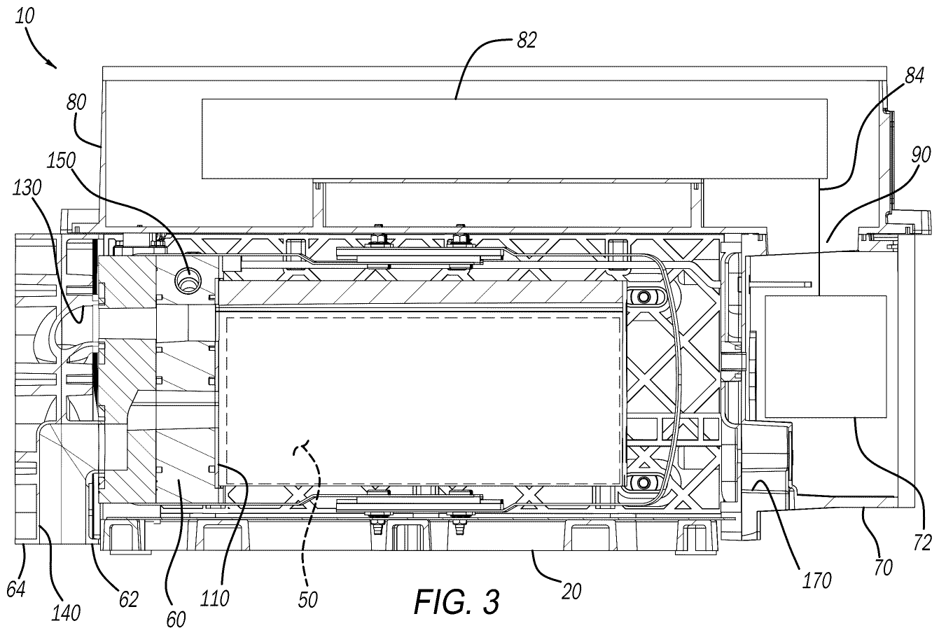

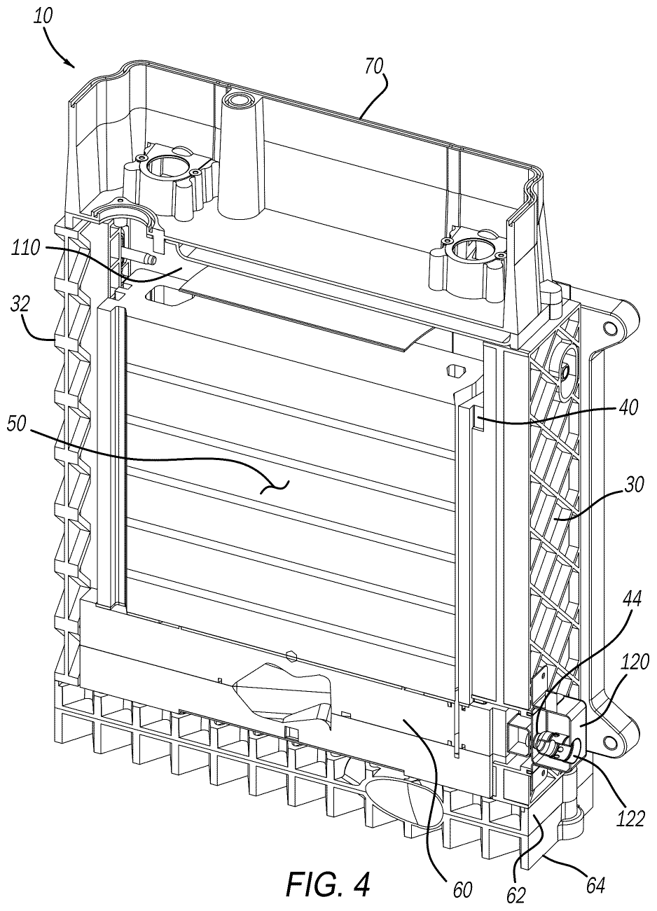

FIGS. 1 and 2 illustrate an example of a fuel cell assembly 10 in accordance with the present disclosure. The fuel cell assembly 10 generally includes a base 20, a first sidewall 30, and a second sidewall 32 (FIG. 2). The first sidewall 30 and the second sidewall 32 are mounted to the base 20. A wet end unit 60 is mounted to a wet end of each of the first sidewall 30 and the second sidewall 32. A first electronics housing 70 is mounted to a dry end of each of the first sidewall 30 and the second sidewall 32, and provides a dry end unit. A second electronics housing 80 is mounted to each of the first sidewall 30, the second sidewall 32, the wet end unit 60, and the first electronics housing 70. A fuel cell housing 110 is defined by each of the first sidewall 30, the second sidewall 32, the wet end unit 60, the first electronics housing 70, and the second electronics housing 80. The second electronics housing 80 generally provides a cover of the fuel cell housing 110. These components are mounted in any suitable manner, such as with any suitable fasteners. With additional reference to FIGS. 3 and 4, the fuel cell housing 110 is configured to accommodate a fuel cell stack subassembly 50 therein. The fuel cell stack subassembly 50 includes a plurality of individual fuel cells stacked within the fuel cell housing 110.

The first sidewall 30, the second sidewall 32, and the wet end unit 60 are made of any suitable non-conductive composite material. The composite material may be any suitable non-metallic material, such as any suitable polymeric material. The composite material may be reinforced in any suitable manner, such as with glass fibers. Each of the base 20, the first electronics housing 70, and the second electronics housing 80 may also be made of the non-conductive composite material, or made of any suitable metallic material, such as aluminum, for example. The non-conductive composite material is lighter than most metallic materials, and thus provides the fuel cell assembly 10 with a reduced weight. The components of the fuel cell assembly 10 may be made of the same non-conductive composite material, or various different non-conductive composite materials. The composite material may be bonded with an EMC shield.

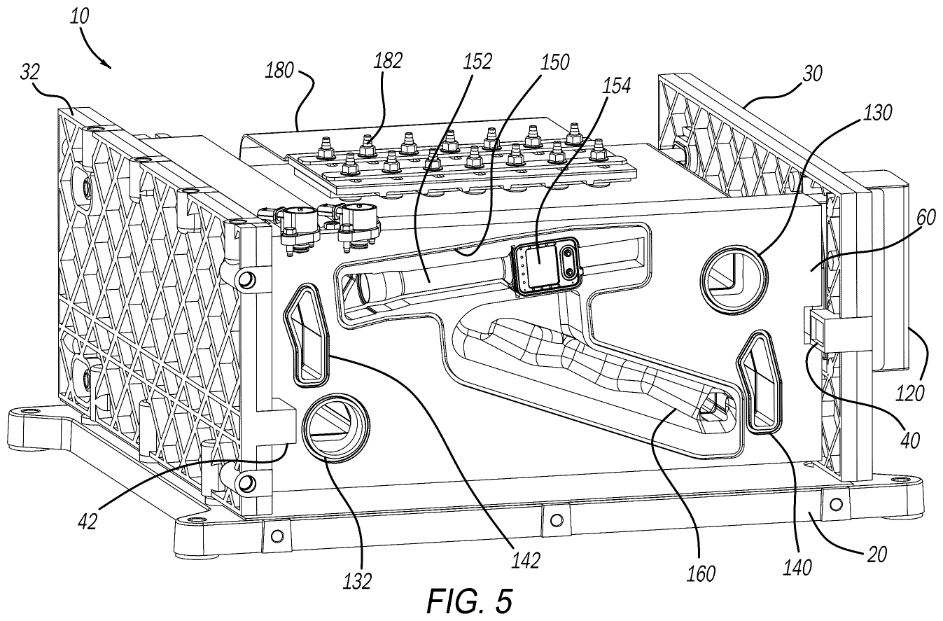

With renewed reference to FIGS. 1 and 2, the first sidewall 30 defines a first groove 34 at an exterior thereof, and the second sidewall 32 defines a second groove 36 at an exterior thereof. The first groove 34 and the second groove 36 are configured to receive any suitable wiring therein to act as a wire harness. Opposite to the first groove 34 is a first rail 40 at an interior of the first sidewall 30, as illustrated in FIGS. 4 and 5, for example. Opposite to the second groove 36 is a second rail 42 at an interior of the second sidewall 32. The first rail 40 is formed integral with the first sidewall 30, and the second rail 42 is formed integral with the second sidewall 32. Thus, the first rail 40 and the first sidewall 30 are monolithic, and the second rail 42 and the second sidewall 32 are monolithic. The first rail 40 and the second rail 42 may be directly opposite to each other and co-planar, or may be offset from each other as illustrated in FIG. 5.

Each one of the first rail 40 and the second rail 42 are configured to cooperate with the fuel cells of the fuel cell stack subassembly 50 to restrict movement of the fuel cell stack subassembly 50 within the fuel cell housing 110. The first rail 40 and the second rail 42 also facilitate insertion of the fuel cells within the fuel cell housing 110. For example, the fuel cells may be individually slid along the first rail 40 and the second rail 42 to stack the fuel cells within the fuel cell housing 110. The fuel cell stack subassembly 50 may alternatively be inserted into the fuel cell housing 110 as a whole and slid along the first rail 40 and the second rail 42.

Each one of the first sidewall 30 and the second sidewall 32 includes one or more slots 46 in cooperation with pins 48. The pins 48 are associated with a support assembly for the fuel cell stack subassembly 50. Cooperation between the pins 48 and the slots 46 is such that the pins 48 are movable within the slots 46 to accommodate a relatively larger or smaller sized fuel cell stack subassembly 50.

The first sidewall 30 defines a window 44 (FIG. 4), which extends through the first sidewall 30 and is in fluid communication with the wet end unit 60. Mounted to the first sidewall 30 over the window 44 is an injector housing 120, which provides a fuel rail attenuating volume. The injector housing 120 includes a plurality of hydrogen injectors 122, which are configured to couple with any suitable hydrogen source and deliver hydrogen to the fuel cell stack subassembly 50. With particular reference to FIG. 5, a hydrogen manifold 150 is in fluid communication with the hydrogen injectors 122 and the injector housing 120. The hydrogen manifold 150 includes an ejector 152 configured to eject the hydrogen into the fuel cells of the fuel cell stack subassembly 50, and a backflow prevention device 154 to prevent hydrogen backflow. A water separator 160 is proximate to the hydrogen manifold 150.

With reference to FIGS. 1-3 and 5, outside of the wet end unit 60 is a wet end manifold including a first end plate 62 and a second end plate 64. The first end plate 62 and the second end plate 64 are made of the non-conductive, composite material. The first end plate 62 is mounted directly to the wet ends of the first sidewall 30 and the second sidewall 32. The second end plate 64 is mounted to the first end plate 62. The first end plate 62, the second end plate 64, and the wet end unit 60 define a plurality of manifolds to deliver oxygen, hydrogen, and coolant to the fuel cells of the fuel cell stack subassembly 50. For example, the first end plate 62, the second end plate 64, and the wet end unit 60 define an air inlet 130 for oxygen, an air outlet 132, a coolant inlet 140, and a coolant outlet 142. The coolant may be any suitable coolant, such as water. As illustrated in FIG. 3, an interface 170 for a header drain is included for draining water from the fuel cell stack subassembly 50.

With particular reference to FIG. 3, the first electronics housing 70 includes a power sensing module 72 of power electronics of the fuel cell assembly 10. The power electronics include any suitable fuel cell power electronics configured to operate and regulate operation of the fuel cell assembly 10 to generate electricity. The power sensing module 72 is in communication with the power conversion unit 82 by way of a wired connection extending through a passageway 90 defined between the first electronics housing 70 and the second electronics housing 80. The first electronics housing 70 further includes electrical connectors 74 at an exterior thereof, which are configured to be connected to any suitable load for supplying electricity generated by the fuel cell assembly 10 to the load.

With continued reference to FIG. 3, the second electronics housing 80 includes a power conversion unit 82. The power conversion unit 82 is configured to, if appropriate, convert electricity generated by the fuel cell assembly 10 for use by a load. For example, the power conversion unit 82 is configured to convert low voltage DC electricity produced by the fuel cell assembly 10 into a usable AC voltage, essentially acting as a bridge between the fuel cell assembly 10 and the power load to ensure stable and efficient power delivery. Although the first electronics housing 70 is described as including the power sensing module 72 and the second electronics housing 80 is described as including the power conversion unit 82, each one of the first electronics housing 70 and the second electronics housing 80 may include any other suitable electronic components of the fuel cell assembly 10.

With reference to FIG. 5, the fuel cell stack subassembly 50 further includes a compression band 180 configured to hold the individual fuel cells of the fuel cell stack subassembly 50 together. A fastener assembly 182 including various fasteners (such as screws and bolts). The compression band 180 may be adjusted to accommodate a greater or smaller number of fuel cells included with the fuel cell stack subassembly 50 depending on the application.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

In this application, including the definitions below, the term “module” or the term “controller” may be replaced with the term “circuit.” The term “module” may refer to, be part of, or include: an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor circuit (shared, dedicated, or group) that executes code; a memory circuit (shared, dedicated, or group) that stores code executed by the processor circuit; other suitable hardware components that provide the described functionality; or a combination of some or all of the above, such as in a system-on-chip.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

The term code, as used above, may include software, firmware, and/or microcode, and may refer to programs, routines, functions, classes, data structures, and/or objects. The term shared processor circuit encompasses a single processor circuit that executes some or all code from multiple modules. The term group processor circuit encompasses a processor circuit that, in combination with additional processor circuits, executes some or all code from one or more modules. References to multiple processor circuits encompass multiple processor circuits on discrete dies, multiple processor circuits on a single die, multiple cores of a single processor circuit, multiple threads of a single processor circuit, or a combination of the above. The term shared memory circuit encompasses a single memory circuit that stores some or all code from multiple modules. The term group memory circuit encompasses a memory circuit that, in combination with additional memories, stores some or all code from one or more modules.

The term memory circuit is a subset of the term computer-readable medium. The term computer-readable medium, as used herein, does not encompass transitory electrical or electromagnetic signals propagating through a medium (such as on a carrier wave); the term computer-readable medium may therefore be considered tangible and non-transitory. Non-limiting examples of a non-transitory, tangible computer-readable medium are nonvolatile memory circuits (such as a flash memory circuit, an erasable programmable read-only memory circuit, or a mask read-only memory circuit), volatile memory circuits (such as a static random access memory circuit or a dynamic random access memory circuit), magnetic storage media (such as an analog or digital magnetic tape or a hard disk drive), and optical storage media (such as a CD, a DVD, or a Blu-ray Disc).

The apparatuses and methods described in this application may be partially or fully implemented by a special purpose computer created by configuring a general purpose computer to execute one or more particular functions embodied in computer programs. The functional blocks, flowchart components, and other elements described above serve as software specifications, which can be translated into the computer programs by the routine work of a skilled technician or programmer.

The computer programs include processor-executable instructions that are stored on at least one non-transitory, tangible computer-readable medium. The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc.

The computer programs may include: (i) descriptive text to be parsed, such as HTML (hypertext markup language), XML (extensible markup language), or JSON (JavaScript Object Notation) (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C #, Objective-C, Swift, Haskell, Go, SQL, R, Lisp, Java®, Fortran, Perl, Pascal, Curl, OCaml, Javascript®, HTML 5 (Hypertext Markup Language 5th revision), Ada, ASP (Active Server Pages), PHP (PHP: Hypertext Preprocessor), Scala, Eiffel, Smalltalk, Erlang, Ruby, Flash®, Visual Basic®, Lua, MATLAB, SIMULINK, and Python®.

What is claimed is

1. A fuel cell assembly comprising:
a base;
a first sidewall mounted to the base, the first sidewall including a first rail extending along a first interior surface of the first sidewall, the first rail configured to cooperate with a fuel cell stack subassembly;
a second sidewall mounted to the base opposite to the first sidewall, the second sidewall including a second rail extending along a second interior surface of the second sidewall, the second rail configured to cooperate with the fuel cell stack subassembly;
a wet end unit mounted to wet ends of each of the first sidewall and the second sidewall, the wet end unit defining a plurality of manifolds configured to deliver hydrogen, oxygen, and coolant to the fuel cell stack subassembly;
a first electronics housing mounted to dry ends of each of the first sidewall and the second sidewall; and
a second electronics housing mounted to each one of the first sidewall, the second sidewall, the wet end unit, and the first electronics housing to provide a cover of a fuel cell housing configured to house the fuel cell stack subassembly.

2. The fuel cell assembly of claim 1, wherein at least the first sidewall, the second sidewall, and the wet end unit are formed from a non-metallic, composite material.

3. The fuel cell assembly of claim 2, wherein the base is formed of the non-metallic, composite material.

4. The fuel cell assembly of claim 1, wherein:
the first sidewall defines a first groove extending along a first exterior surface of the first sidewall opposite to the first rail; and
the second sidewall defines a second groove extending along a second exterior surface of the second sidewall opposite to the second rail.

5. The fuel cell assembly of claim 1, wherein the first electronics housing includes a power sensing module and the second electronics housing includes a power conversion unit in wired communication with the power sensing module by way of a passageway defined between the first electronics housing and the second electronics housing.

6. The fuel cell assembly of claim 1, wherein at least one of the first electronics housing and the second electronics housing is made of a non-metallic composite material.

7. The fuel cell assembly of claim 1, wherein the first electronics housing is a dry end unit of the fuel cell assembly.

8. The fuel cell assembly of claim 1, wherein the first electronics housing includes electrical connectors configured for connection to a load to deliver electricity generated by the fuel cell assembly to the load.

9. The fuel cell assembly of claim 1, wherein the plurality of manifolds of the wet end unit includes an air inlet, an air outlet, a coolant inlet, a coolant outlet, and a hydrogen inlet.

10. The fuel cell assembly of claim 9, wherein the first sidewall defines a window in fluid communication with the hydrogen inlet and hydrogen injectors mounted to the first sidewall, the hydrogen injectors configured to cooperate with a hydrogen source for delivering hydrogen to the fuel cell stack subassembly.

11. The fuel cell assembly of claim 1, further comprising a wet end manifold including a first end plate mounted to the first sidewall and the second sidewall, and a second end plate mounted to the first end plate,
wherein the plurality of manifolds are defined by the wet end unit, the first end plate, and the second end plate, and the plurality of manifolds include a hydrogen manifold and a hydrogen ejector.

12. The fuel cell assembly of claim 1, further comprising a drain in fluid communication with the fuel cell housing configured to drain coolant out of the fuel cell housing.

13. The fuel cell assembly of claim 1, wherein:
the first rail is integrally formed with the first sidewall, and the second rail is integrally formed with the second sidewall; and
cooperation between the first rail and the fuel cell stack subassembly, and cooperation between the second rail and the fuel cell stack subassembly, restricts movement of the fuel cell stack within the fuel cell housing.

14. The fuel cell assembly of claim 1, wherein the fuel cell housing is defined by the base, the first sidewall, the second sidewall, the wet end unit, the first electronics housing, and the second electronics housing.

15. A fuel cell assembly comprising:
a wet end unit made of a non-conductive composite material and defining a plurality of manifolds configured to deliver hydrogen, oxygen, and coolant to a fuel cell stack subassembly seated within the fuel cell assembly;
a first electronics housing including first power components and electrical connectors configured for connection to a load to deliver electricity generated by the fuel cell assembly to the load;
a first sidewall made of the non-conductive composite material and extending from the wet end unit to the first electronics housing;
a second sidewall made of the non-conductive composite material and extending from the wet end unit to the first electronics housing;
a base mounted to the first electronics housing, the first sidewall, and the second sidewall;
a second electronics housing including second power components, the second electronics housing mounted to the wet end unit, the first electronics housing, the first sidewall, and the second sidewall; and
a fuel cell housing defined by each of the wet end unit, the first electronics housing, the first sidewall, the second sidewall, the base, and the second electronics housing, the fuel cell housing configured to house the fuel cell stack subassembly therein.

16. The fuel cell assembly of claim 15, wherein:
the first sidewall includes an integral first rail at a first inner surface of the first sidewall;
the second sidewall includes an integral second rail at a second inner surface of the second sidewall; and
the fuel cell stack subassembly is in cooperation with each of the integral first rail and the integral second rail to restrict movement of the fuel cell stack subassembly within the fuel cell housing.

17. The fuel cell assembly of claim 15, wherein the first electronics housing and the second electronics housing each include a composite material bonded with an electromagnetic compatibility (EMC) shield.

18. A fuel cell assembly comprising:
a base;
a first sidewall mounted to the base;
a second sidewall mounted to the base;
a wet end unit mounted to wet ends of each of the first sidewall and the second sidewall, the wet end unit defining a plurality of manifolds for hydrogen, oxygen, and coolant;
a first electronics housing mounted to dry ends of each of the first sidewall and the second sidewall, the first electronics housing including a power sensing module therein;
a second electronics housing mounted to each one of the first sidewall, the second sidewall, the wet end unit, and the first electronics housing, the second electronics housing including a power conversion unit in wired connection with the power sensing module by way of a passageway defined between the first electronics housing and the second electronics housing;
a fuel cell housing defined by each of the base, the first sidewall, the second sidewall, the wet end unit, the first electronics housing, and the second electronics housing; and
a fuel cell stack subassembly seated within the fuel cell housing and in cooperation with a first rail of the first sidewall and a second rail of the second sidewall, the plurality of manifolds are in fluid cooperation with the fuel cell stack subassembly to deliver hydrogen, oxygen, and coolant thereto,
wherein the first sidewall, the second sidewall, and the wet end unit are formed of a non-conductive polymeric material.

19. The fuel cell assembly of claim 18, wherein the base, the first electronics housing, and the second electronics housing are formed of the non-conductive polymeric material.

20. The fuel cell assembly of claim 18, further comprising a drain in fluid communication with the fuel cell housing configured to drain coolant out of the fuel cell housing.
